(19) United States
(12) Patent Application Publication
(10) Pub. No.: US 2025/0280722 A1
(43) Pub. Date: Sep. 4, 2025

(54) Display Apparatus

(71) Applicant: LG Display Co., Ltd., Seoul (KR)

(72) Inventor: HyunSeok Hong, Gumi-si (KR)

(21) Appl. No.: 18/810,037

(22) Filed: Aug. 20, 2024

(30) Foreign Application Priority Data
Feb. 29, 2024 (KR) 10-2024-0029547

(51) Int. Cl. H10K 59/88; H10K 59/131; H10K 59/80

(52) U.S. Cl. CPC H10K 59/88; H10K 59/131; H10K 59/873

(57) ABSTRACT

A display apparatus includes a substrate including a display area in which a plurality of pixels is disposed, and a non-display area outside the display area. The non-display area includes a first non-display area surrounding the display area and a second non-display area extended and bent at one side of the first non-display area. The display apparatus further includes a high-potential voltage line disposed at the one side of the first non-display area on the substrate, and supplying high-potential voltage to the plurality of pixels. The display apparatus further includes a first dummy metal disposed at the one side of the first non-display area on the substrate, disposed between the high-potential voltage line and the second non-display area, and electrically insulated from the high-potential voltage line.

### CROSS-REFERENCE TO RELATED APPLICATION

This application claims the priority of Republic of Korea Patent Application No. 10-2024-0029547 filed on Feb. 29, 2024, which is incorporated herein by reference in its entirety.

### BACKGROUND

### Technical Field

The present disclosure relates to a display apparatus, and more particularly, to a display apparatus which suppresses occurrence of moisture penetration at an outer portion of a display panel.

### Description of the Related Art

As an information age enters, a field of display apparatus for visually displaying electrical information signals is rapidly developing, and researches for developing performances such as thinning, weight reduction, and low power consumption for various display apparatuses continue.

Exemplary display apparatuses include a liquid crystal display (LCD) apparatus, an electro-wetting display (EWD) apparatus, an organic light-emitting display (OLED) apparatus, and the like.

Unlike liquid crystal display apparatus, a field emission display apparatus operates as a self-luminous display apparatus and does not require a separate light source, as such the field emission display apparatus can be light and thin. Further, the field emission display apparatus is not only advantageous in terms of power consumption by low voltage driving, but also excellent even in color implementation, a response speed, a viewing angle, and a contrast ratio (CR), so the field emission display apparatus is expected to be utilized in various fields.

### SUMMARY

An objective to be achieved by the present disclosure is to provide a display apparatus which may suppress moisture permeability due to film lifting which may occur around a bending region of a display panel.

Another objective to be achieved by the present disclosure is to provide a display apparatus that suppresses panel damage by alleviating bending stress of the display panel.

Objectives of the present disclosure are not limited to the above-mentioned objectives, and other objectives, which are not mentioned above, can be clearly understood by those skilled in the art from the following descriptions.

According to an aspect of the present disclosure, a display apparatus includes: a substrate including a display area in which a plurality of pixels is disposed, and a non-display area outside the display area, in which the non-display area includes a first non-display area surrounding the display area and a second non-display area extended and bent at one side of the first non-display area; a high-potential voltage line disposed at one side of the first non-display area on the substrate, and supplying high-potential voltage to the plurality of pixels; and a first dummy metal disposed at one side of the first non-display area on the substrate, disposed between the high-potential voltage line and the second non-display area, and electrically insulated from the high-potential voltage line.

Other detailed matters of the exemplary embodiments are included in the detailed description and the drawings.

In a display apparatus according to an exemplary embodiment of the present disclosure, a high-potential voltage line disposed in a non-display area of a display panel is disposed to be as far as possible from a bending region to suppress film lifting which may occur around the bending region and moisture permeability failure caused due to the film lifting.

Further, in the display apparatus according to an exemplary embodiment of the present disclosure, dummy metal insulated from the high-potential voltage line is disposed between the high-potential voltage line and the bending region to alleviate bending stress of the display panel, thereby suppressing damage to the display panel.

According to another aspect of the present disclosure, a display apparatus includes a substrate. The substrate includes a display area in which an image is displayed, a bending area that bends, and a link area extending in a first direction between the display area and the bending area. The display area also includes a light-emitting element disposed on the substrate in the display area, and a thin film transistor disposed between the light-emitting element and the substrate in the display area. The thin film transistor is electrically connected to the light-emitting element. The display area further includes a supply voltage line disposed in the link area. At least a part of the supply voltage line extends in the first direction traversing from the link area to the bending area. The display apparatus further includes a dummy metal adjacent to the supply voltage line in a second direction intersecting the first direction. The dummy metal is electrically insulated from the supply voltage. In some embodiments, the dummy metal and the supply voltage line are disposed in a same layer, and include a same material.

The effects of the present disclosure are not limited to the aforementioned effects, and other effects, which are not mentioned above, will be apparently understood to a person having ordinary skill in the art from the following description.

### BRIEF DESCRIPTION OF DRAWINGS

The above and other aspects, features and other advantages of the present disclosure will be more clearly understood from the following detailed description taken in conjunction with the accompanying drawings.

FIG. 1 is a block diagram of a display apparatus according to an exemplary embodiment of the present disclosure.

FIG. 2 is a plan view of a display panel according to an exemplary embodiment of the present disclosure.

FIG. 3 is a plan view for explaining a layout structure of a power supply line and dummy metal included in the display panel according to an exemplary embodiment of the present disclosure.

FIG. 4 is a circuit diagram of a subpixel in the display apparatus according to an exemplary embodiment of the present disclosure.

FIG. 5 is a cross-sectional view of a subpixel disposed in a display area of the display panel according to an exemplary embodiment of the present disclosure.

FIG. 6 is an enlarged view of part A of FIG. 3, illustrating a layout structure of the dummy metal of the display panel according to an exemplary embodiment of the present disclosure.

FIG. 7 is a cross-sectional view taken along line I-I′ of FIG. 6 according to an exemplary embodiment of the present disclosure.

FIG. 8 is an enlarged view of part A of FIG. 3, illustrating a layout structure of the dummy metal of the display panel according to an exemplary embodiment of the present disclosure.

FIG. 9 is a cross-sectional view taken along line II-II′ of FIG. 8 according to an exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification.

Further, in the following description of the present disclosure, a detailed explanation of known related technologies may be omitted to avoid unnecessarily obscuring the subject matter of the present disclosure.

The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly” is not used.

When an element or layer is referred to as being “on” another element or layer, it may be directly on the other element or layer, or intervening elements or layers may be present therebetween.

When a component is “linked”, “coupled”, or “connected” to another component, the component may be directly linked or connected to the other component. However, unless specifically stated otherwise, it should be understood that a third component may be interposed between the components which may be indirectly linked or connected.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure. Like reference numerals generally denote like elements throughout the specification.

Like reference numerals generally denote like elements throughout the specification.

A size and a thickness of each component illustrated in the drawings are illustrated for convenience of explanation, and are not limited to the size and the thickness of the component illustrated in embodiments of the present disclosure.

The features of various embodiments of the present disclosure can be partially or entirely coupled to or combined with each other and can be interlocked and operated in technically various ways, and respective embodiments can be carried out independently of or in association with each other.

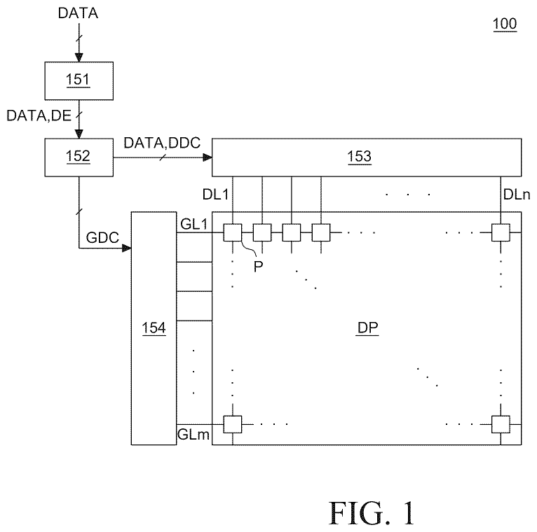

FIG. 1 is a block diagram of a display apparatus according to an exemplary embodiment of the present disclosure.

Referring to FIG. 1, the display apparatus 100 according to an exemplary embodiment of the present disclosure may include an image processor 151, a timing controller 152, a data driver 153, a gate driver 154, and a display panel DP.

The image processor 151 outputs a driving signal including a data signal DATA and a data enable signal DE supplied from the outside. The image processor 151 may output a driving signal including one or more of a vertical synchronization signal, a horizontal synchronization signal, and a clock signal in addition to the data enable signal DE.

The timing controller 152 receives the driving signal and the data signal DATA including the data enable signal DE, etc. from the image processor 151. The timing controller 152 outputs a gate timing control signal GDC for controlling an operation timing of the gate driver 154 based on the driving signal. The timing controller 152 outputs the data signal DATA supplied from the image processor 151, and a data timing control signal DDC for controlling an operation timing of the data driver 153.

In response to the data timing control signal DDC supplied from the timing controller 152, the data driver 153 samples and latches the data signal DATA supplied from the timing controller 152 and converts the sampled and latched data signal into gamma reference voltage and outputs the gamma reference voltage. Further, the data driver 153 outputs data signals through data lines DL1 to DLn.

The gate driver 154 may output a gate signal in response to the gate timing control signal GDC supplied from the timing controller 152, and at this time, the gate driver may shift a level of gate voltage, and output the gate signal. Further, the gate driver 154 outputs gate signals through gate lines GL1 to GLn.

The display panel DP includes a plurality of pixels P, and each of the plurality of pixels P emits light in response to the data signal and the gate signal supplied from the data driver 153 and the gate driver 154 to display an image.

One pixel P may be constituted by a plurality of subpixels. For example, one pixel P may include three or more subpixels that emit light of different colors. For example, in the display apparatus 100 according to an exemplary embodiment of the present disclosure, one pixel P may include subpixels that emit red, green, and blue. However, the number of subpixels included in one pixel P is not limited, and for example, may also further include a subpixel that emits white in addition to the subpixels that emit the red, the green, and the blue.

A plurality of gate lines GL1 to GLm extended in a first direction and a plurality of data lines DL1 to DLn extended in a second direction different from the first direction are disposed to cross on the display panel DP. Pixels P are defined at respective points where the plurality of gate lines and data lines cross on the display panel DP.

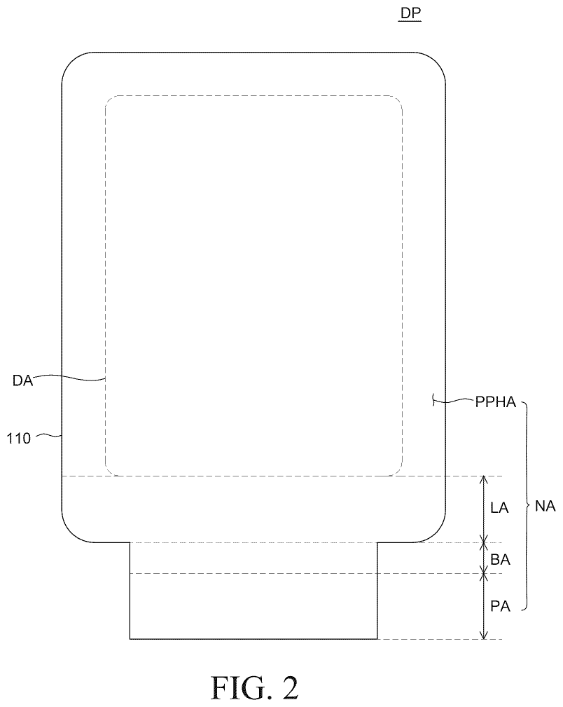

FIG. 2 is a plan view of a display panel according to an exemplary embodiment of the present disclosure.

Referring to FIG. 2, the display panel DP includes a substrate 110.

The substrate 110 is configured to support various components included in the display apparatus 100. The substrate 110 may be made of an insulation material. The substrate 110 may be made of a transparent material. Further, the substrate 110 may be a rigid substrate, or a flexible substrate which is bendable, foldable, rollable, or the like. In addition, the substrate 110 may be made of glass or a plastic material having flexibility. For example, when the substrate 110 is made of polyimide (PI) which is the plastic material, a manufacturing process of the display apparatus 100 is performed in a state that a support substrate made of glass is disposed below the substrate 110 and after the manufacturing process of the display apparatus 100 is completed, the support substrate may be released.

As illustrated in FIG. 2, the substrate 110 of the display panel DP may be defined as a display area DA, and a non-display area NA which is positioned outside the display area DA, and in which a plurality of pixels P is not disposed.

The non-display area NA of the substrate 110 may be defined as a peripheral area PPHA surrounding a periphery of the display area DA, a bending area BA extended from one side of the peripheral area PPHA and bent toward a rear surface of the display panel DP, and a pad area PA extended from the bending area BA. Further, one side of the peripheral area PPHA of the substrate 110 may be defined as a link area LA, and the link area LA is positioned between the display area DA and the bending area BA.

Since the non-display area NA is not an area in which the image is displayed, the non-display area NA need not be viewed on a front of the display panel DP. Therefore, a partial area of the non-display area NA of the substrate 110 may be bent toward the rear surface of the display panel DP, and for example, one edge of the substrate 110 may be bent toward the rear surface of the display panel DP to have a predetermined curvature. In this case, the pad area PA may be positioned to overlap the display area DA on the rear surface of the display panel DP. Through this, the non-display area NA may be reduced while securing an area for the line and a driving circuit.

As illustrated in FIG. 2, the bending area BA is positioned between the display area DA and the pad area PA in the non-display area NA, which bends a part of the non-display area NA in one direction (i.e., in the direction of the rear surface of the display panel DP). At this time, at least a part of the pad area PA may be disposed to overlap the display area DA on the rear surface of the display panel DP as the substrate 110 is bent in the bending area BA.

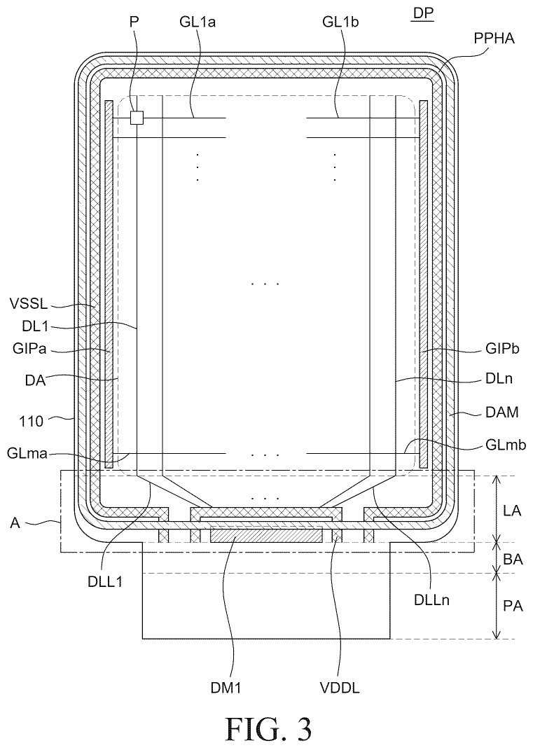

Hereinafter, a structure of the display apparatus 100 according to an exemplary embodiment of the present disclosure will be described in detail with reference to FIGS. 3 to 5 jointly.

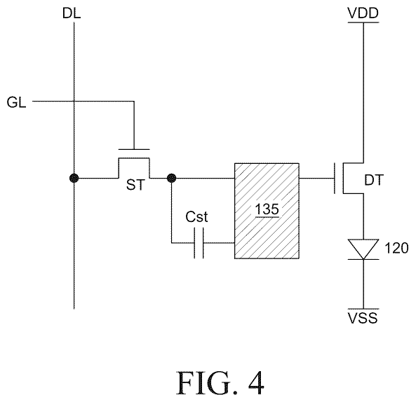

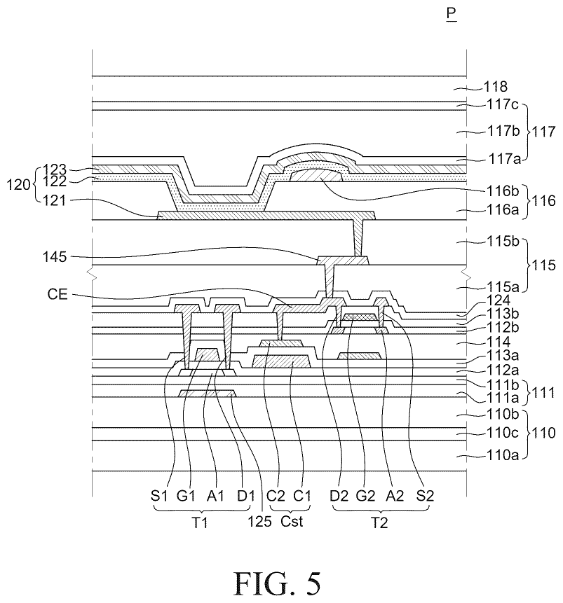

FIG. 3 is a plan view for explaining a layout structure of a power supply line and dummy metal included in the display panel according to an exemplary embodiment of the present disclosure. FIG. 4 is a circuit diagram of a subpixel in the display apparatus according to an exemplary embodiment of the present disclosure. In addition, FIG. 5 is a cross-sectional view of a pixel disposed in a display area of the display panel according to an exemplary embodiment of the present disclosure.

Referring to FIG. 3, the display area DA of the substrate 110 is an area where a plurality of pixels P implementing an image is disposed, and data lines DL1 to DLn extended in the first direction, and gate lines GL1a to GLma: GLa, GL1b to GLmb extended in the second direction may be disposed to cross each other in the display area DA, and pixels P may be disposed at every crossing areas in the form of a matrix.

One pixel P may include a plurality of subpixels each including a light emitting diode and a pixel driving circuit for controlling a current amount which flows on the light emitting diode. The pixel driving circuit may include a plurality of thin film transistors TFT.

In the present disclosure, it is assumed and described that the display apparatus 100 is an organic light emitting diode display apparatus, but the present disclosure is not limited thereto. For example, when the display apparatus 100 is the organic light emitting diode display apparatus, the subpixel may include a light emitting diode 120 including an anode 121, a light emitting layer 122 on the anode 121, and a cathode 123 on the light emitting layer 122. At this time, the light emitting diode 120 as the light emitting layer 122 may include an organic light emitting layer, and may further include a hole transport layer, a hole injection layer, an electron injection layer, and an electron transport layer in addition to the organic light emitting layer. Meanwhile, as another example, when the display apparatus 100 is a liquid crystal display apparatus, the display apparatus 100 may also be configured to include a liquid crystal layer which is a display part.

Referring to FIG. 3, the pixel driving circuit of the subpixel according to an exemplary embodiment of the present disclosure may include a driving transistor DT, a switching transistor ST, a capacitor Cst, a gate line GL, a data line DL, and lines connected to power supplies VDD and VSS for pixel driving.

The light emitting diode 120 may operate to emit light according to a driving current formed by the driving transistor DT. The switching transistor ST may perform a switching operation so that the data signal supplied through the data line DL is stored in the capacitor Cst as data voltage in response to the gate signal supplied through the gate line GL. The driving transistor DT may operate so that constant driving current flows between a high-potential power supply VDD and a low-potential power supply VSS in response to the data voltage stored in the capacitor Cst.

Hereinabove, it is described as an example that in the display apparatus 100 according to an exemplary embodiment of the present disclosure, the subpixel is configured in a 2-transistor (T) 1-capacitor (C) structure including one switching transistor ST, one driving transistor DT, and one capacitor Cst.

As another example, as illustrated in FIG. 4, the subpixel may further include a compensation circuit 135.

The compensation circuit 135 may be a circuit for compensating threshold voltage, etc. of the driving transistor DT and the compensation circuit 135 may include one or more thin film transistors and capacitors. In this case, configurations and structures of a compensation thin film transistor and a compensation capacitor are not limited, and may be diversified according to a compensation type. For example, when the compensation circuit 135 is added to the subpixel, there may be various structures including 3T1C, 4T2C, 5T2C, 6T1C, 6T2C, 7T1C, 7T2C, etc.

Referring to FIG. 5, the structure of the pixel P disposed in the display area DA of the substrate 110 will be described in detail. In FIG. 5, a stacking structure of any one subpixel constituting the pixel P is illustrated as an example.

Referring to FIG. 5, the display apparatus 100 according to an exemplary embodiment of the present disclosure may include a substrate 110, a first buffer layer 111, a metallic layer 125, a first thin film transistor T1, a first gate insulation layer 112a, a first interlayer insulation layer 113a, a second buffer layer 114, a second thin film transistor T2, a second gate insulation layer 112b, a second interlayer insulation layer 113b, a connection electrode C, a planarization layer 115, an auxiliary electrode 145, a bank part 116, a light emitting diode 120, and an encapsulation part 117 (also referred to herein as an encapsulation layer).

The substrate 110 serves to support and protect components of the display apparatus disposed thereabove.

For example, when the substrate 110 is made of polyimide (PI), moisture penetrates up to the thin film transistor or the light emitting diode through the substrate 110 made of polyimide (PI), which may degrade the performance of the display apparatus 100. In order to suppress the degradation of the performance of the display apparatus 100 due to the moisture penetration, a double polyimide (PI) structure may be adopted as the substrate 110 in the display apparatus 100 according to an exemplary embodiment of the present disclosure.

For example, as illustrated in FIG. 5, the substrate 110 may include a first substrate 110a and a second substrate 110b each made of polyimide (PI), and an inorganic insulation layer 110c formed between the first substrate 110a and the second substrate 110b.

The inorganic insulation layer 110c may be configured by a single layer of silicon nitride (SiNx) or silicon oxide (SiOx), or multiple layers thereof. For example, a silicon dioxide (SiO2) material may be used as the inorganic insulation layer 110c, but the present disclosure is not limited thereto, and the inorganic insulation layer 110c may also be configured by double layers of silicon dioxide (SiO2) and silicon nitride (SiNx).

The inorganic insulation layer 110c blocks penetration of moisture into an upper portion of the second substrate 110b. Further, when an electric charge is charged into the first substrate 110a, the inorganic insulation layer 110c may block the charged electric charge from affecting the first thin film transistor T1 through the second substrate 110b. As described above, an electric charge charged in lower polyimide (PI) is blocked by the inorganic insulation layer 110c to improve the reliability of a product, and a layout process of a separate metallic layer for blocking the electric charge may be omitted, so the process may be simplified and production cost may be reduced.

The first buffer layer 111 is disposed on the substrate 110.

For example, as illustrated in FIG. 5, the first buffer layer 111 may include multi-buffer layers 111a and an active buffer layer 111b, and the multi-buffer layers 111a may be disposed on the substrate 110, and the active buffer layer 111b may be disposed on the multi-buffer layers 111a.

The metallic layer 125 may be disposed between the multi-buffer layers 111a and the active buffer layer 111b. That is, the metallic layer 125 is disposed on the multi-buffer layers 111a, and the active buffer layer 111b is disposed on the metallic layer 125. The metallic layer 125 may serve as a light shield, and may also be referred to as a light shielding layer.

The first thin film transistor T1 is disposed on the first buffer layer 111.

The first thin film transistor T1 includes a first active layer A1, a first gate electrode G1, a first source electrode S1, and a first drain electrode D1. However, the first source electrode S1 may become the first drain electrode, and the first drain electrode D1 may become the first source electrode.

The first active layer A1 is disposed on the first buffer layer 111. The first active layer A1 may include amorphous silicon or polycrystalline silicon. For example, the first active layer A1 may include low-temperature poly silicon (LTPS). Since a poly silicon material is high in mobility (100 cm²/Vs or higher), low in energy consumption power, and excellent in reliability, the poly silicon material may be applied to a gate driver for a driving device and/or a multiplexer (MUX) for driving the thin film transistors for a display device. It is described that in the display apparatus 100 according to an exemplary embodiment of the present disclosure, the low-temperature poly silicon (LTPS) is adopted as the active layer A1 of the first thin film transistor T1, but the low-temperature poly silicon (LTPS) may also be adopted as the active layer A2 of the second thin film transistor T2 according to characteristics of the display apparatus 100. Further, in the display apparatus 100 according to an exemplary embodiment of the present disclosure, the first active layer A1 adopting the low-temperature poly silicon (LTPS) may be adopted as the active layer of the driving transistor, but the present disclosure is not limited thereto. For example, the first active layer A1 may also be adopted as the active layer of the switching transistor.

The first active layer A1 may include a first channel area in which a channel is formed when the first thin film transistor T1 is driven, and a first source area and a first drain area on both sides of the first channel area. The first source area of the first active layer A1 is connected to the first source electrode S1, and the first drain area is connected to the first drain electrode D1. For example, the first source area and the first drain area may be configured by ion doping (impurity doping) of the first active layer A1. The first source area and the first drain area may be generated by ion-doping the poly silicon material and in this case, the first channel area may mean a portion which is not ion-doped but left as the poly silicon material.

The first gate insulation layer 112a is disposed on the first active layer A1.

The first gate insulation layer 112a may be disposed throughout the substrate 110 including the first active layer A1. For example, the first gate insulation layer 112a may be configured by a single layer of silicon nitride (SiNx) or silicon oxide (SiOx), or multiple layers thereof. Contact holes may be formed in the first gate insulation layer 112a in order to connect the first source electrode S1 and the first drain electrode D1 of the first thin film transistor T1 to the first source area and the first drain area of the first active layer A1 of the first thin film transistor T1, respectively.

The first gate electrode G1 of the first thin film transistor T1 and the first capacitor electrode C1 of the storage capacitor Cst are disposed on the first gate insulation layer 112a.

The first gate electrode G1 and the first capacitor electrode C1 may be configured by a single layer or multiple layers made of any one of molybdenum (Mo), copper (Cu), titanium (Ti), aluminum (Al) chromium (Cr), gold (AU), nickel (Ni), and neodymium (Nd), or an alloy thereof.

The first gate electrode G1 may be formed on the first gate insulation layer 112a so as to overlap the first channel area of the first active layer A1 of the first thin film transistor T1.

The first capacitor electrode C1 may also be omitted based on the driving characteristics of the display apparatus 100, and the structure and the type of thin film transistor. The first gate electrode G1 and the first capacitor electrode C1 may be made of the same material, and formed on the same layer. That is, the first gate electrode G1 and the first capacitor electrode C1 may be formed by the same process.

The first interlayer insulation layer 113a is disposed above the first gate insulation layer 112a, the first gate electrode G1, and the first gate electrode C1.

The first interlayer insulation layer 113a may be configured by a single layer of silicon nitride (SiNx) or silicon oxide (SiOx), or multiple layers thereof. In addition, contact holes for exposing the first source area and the first drain area of the first active layer A1 of the first thin film transistor T1 may be formed on the first interlayer insulation layer 113a.

The second capacitor electrode C2 of the storage capacitor Cst is disposed on the first interlayer insulation layer 113a.

The second capacitor electrode C2 may be configured by a single layer or multiple layers made of any one of molybdenum (Mo), copper (Cu), titanium (Ti), aluminum (Al) chromium (Cr), gold (AU), nickel (Ni), and neodymium (Nd), or an alloy thereof. The second capacitor electrode C2 may be formed on the first interlayer insulation layer 113a to overlap the first capacitor electrode C1. Further, the second capacitor electrode C2 may be made of the same material as the first capacitor electrode C1. The second capacitor electrode C2 may also be omitted based on the driving characteristics of the display apparatus 100, and the structure and the type of thin film transistor.

The second buffer layer 114 is disposed on the first interlayer insulation layer 113a and the second capacitor electrode C2.

The second buffer layer 114 may be configured by a single layer of silicon nitride (SiNx) or silicon oxide (SiOx), or multiple layers thereof. Contact holes for exposing the first source area and the first drain area of the first active layer A1 of the first thin film transistor T1 may be formed on the second buffer layer 114. Further, a contact hole for exposing the second capacitor electrode C2 of the storage capacitor Cst may be formed on the second buffer layer 114.

The second thin film transistor T2 is disposed on the second buffer layer 114.

The second thin film transistor T2 includes a second active layer A2, a second gate electrode G2, a second source electrode S2, and a second drain electrode D2. According to the design of the pixel circuit, the second source electrode S2 may become the second drain electrode, and the second drain electrode D2 may become the second source electrode.

The second active layer A2 is disposed on the second buffer layer 114. The second active layer A2 may be made of an oxide semiconductor. Since an oxide semiconductor material has a larger band gap than the silicon material, electrons may not cross the band gap in an off state, and as a result, off-current is low. Accordingly, a thin film transistor including the active layer made of the oxide semiconductor may be suitable for a switching transistor in which an on time is short and an off time is maintained to be long, but the present disclosure is not limited thereto, and the thin film transistor may also be adopted as the driving transistor according to the characteristics of the display apparatus 100. In addition, since the off-current is low, the size of an auxiliary capacitance may be reduced, and as a result, the thin film transistor including the active layer made of the oxide semiconductor is suitable for a high-resolution display device. For example, the second active layer A2 is made of a metal oxide and may be made of various metal oxides such as indium-gallium-zinc-oxide (IGZO), etc. In an exemplary embodiment of the present disclosure, it is assumed and described that the second active layer A2 of the second thin film transistor T2 is made of IGZO among various metal oxides, but the present disclosure is not limited thereto, and the second active layer A2 may also be made of other metal oxides such as indium-zinc-oxide (IZO), indium-gallium-tin-oxide (IGTO), or indium-gallium-oxide (IGO). The second active layer A2 may be formed by depositing the metal oxide on the second buffer layer 114, performing a heat treatment process for stabilization, and then patterning the metal oxide.

The second active layer A2 may include a second channel area in which a channel is formed when the second thin film transistor T2 is driven, and a second source area and a second drain area on both sides of the second channel area. The second source area of the second active layer A2 is connected to the second source electrode S2, and the second drain area is connected to the second drain electrode D2.

In the display apparatus 100 according to an exemplary embodiment of the present disclosure, the light shielding layer serving the light shield may also be disposed below the second thin film transistor T2. For example, as illustrated in FIG. 5, a metallic layer performing the same function as the metallic layer 125 described above may be further disposed below the second buffer layer 114, and the metallic layer may be disposed to overlap the second active layer A2 on the first interlayer insulation layer 113a.

The second gate insulation layer 112b is disposed on the second active layer A2.

The second gate insulation layer 112b may be disposed throughout the substrate 110 including the second active layer A2. For example, the second gate insulation layer 112b may be configured by a single layer of silicon nitride (SiNx) or silicon oxide (SiOx), or multiple layers thereof.

The second gate electrode G2 may be disposed on the second gate insulation layer 112b. The second gate electrode G2 may be configured by a single layer or multiple layers made of any one of molybdenum (Mo), copper (Cu), titanium (Ti), aluminum (Al), chromium (Cr), gold (AU), nickel (Ni), and neodymium (Nd), or an alloy thereof.

For example, a metallic material is formed on the second gate insulation layer 112b, a photoresist pattern is formed on the metallic material, and then the metallic material is wet-etched by using the photoresist pattern as a mask to form the second gate electrode G2. A wet etching liquid for etching the metallic material may adopt a material which selectively etches molybdenum (Mo), copper (Cu), titanium (Ti), aluminum (Al) chromium (Cr), gold (AU), nickel (Ni), neodymium (Nd), and/or an alloy thereof, and does not etch an insulation material.

The second interlayer insulation layer 113b may be disposed on the second gate insulation layer 112b and the second gate electrode G2.

Contact holes for exposing the first active layer A1 of the first thin film transistor T1 and the second active layer A2 of the second thin film transistor T2 may be formed on the second interlayer insulation layer 113b. For example, contact holes for exposing the first source area and the first drain area of the first active layer A1 in the first thin film transistor T1 may be formed on the second interlayer insulation layer 113b. Further, contact holes for exposing the second source area and the second drain area of the second active layer A2 in the second thin film transistor T2 may be formed on the second interlayer insulation layer 113b.

The second interlayer insulation layer 113b may be configured by a single layer of silicon nitride (SiNx) or silicon oxide (SiOx), or multiple layers thereof.

The connection electrode CE, the first source electrode S1 and the second drain electrode D1 of the first thin film transistor T1, and the second source electrode S2 and the second drain electrode D2 of the second thin film transistor T2 may be disposed above the second interlayer insulation layer 113b.

The connection electrode CE may be electrically connected to the second drain electrode D2 of the second thin film transistor T2. In addition, the connection electrode CE may be electrically connected to the second capacitor electrode C2 of the storage capacitor Cst through the contact holes formed on the second buffer layer 114 and the second interlayer insulation layer 113b. That is, the connection electrode CE may serve to electrically connect the second capacitor electrode C2 of the storage capacitor Cst and the second drain electrode D2 of the second thin film transistor T2.

Here, the first source electrode S1 and the first drain electrode D1 of the first thin film transistor T1 may be connected to the first active layer A1 of the first thin film transistor T1 through the contact holes formed on the first gate insulation layer 112a, the first interlayer insulation layer 113a, the second buffer layer 114, and the second interlayer insulation layer 113b, respectively.

Further, the second source electrode S2 and the second drain electrode D2 of the second thin film transistor T2 may be connected to the second active layer A2 through the contact hole formed on the second interlayer insulation layer 113b.

The connection electrode CE, the first source electrode S1 and the second drain electrode D1 of the first thin film transistor T1, and the second source electrode S2 and the second drain electrode D2 of the second thin film transistor T2 may be made of the same material by the same process.

For example, the connection electrode CE, the first source electrode S1 and the second drain electrode D1 of the first thin film transistor T1, and the second source electrode S2 and the second drain electrode D2 of the second thin film transistor T2 may be configured by a single layer or multiple layers made of any one of molybdenum (Mo), copper (Cu), titanium (Ti), aluminum (Al) chromium (Cr), gold (AU), nickel (Ni), and neodymium (Nd), or an alloy thereof. For example, the connection electrode CE, the first source electrode S1 and the second drain electrode D1 of the first thin film transistor T1, and the second source electrode S2 and the second drain electrode D2 of the second thin film transistor T2 may be configured in a three-layer structure of titanium (Ti)/aluminum (Al)/titanium (Ti), and are not limited thereto.

The connection electrode CE may be integrally formed to be connected to the second drain electrode D2 of the second thin film transistor T2, but the present disclosure is not limited thereto.

The inorganic material layer 124 is disposed on the connection electrode CE, the first source electrode S1 and the second drain electrode D1 of the first thin film transistor T1, the second source electrode S2 and the second drain electrode D2 of the second thin film transistor T2, and the second interlayer insulation layer 113b.

The inorganic material layer 124 as a passivation layer for protecting the first thin film transistor T1 and the second thin film transistor T2 may be made of silicon oxide (SiOx), silicon nitride (SiNx), or multiple layers thereof.

A first planarization layer 115a of the planarization layer 115 is disposed on the inorganic material layer 124.

The first planarization layer 115a may be an organic layer for planarizing and protecting the upper portions of the first thin film transistor T1 and the second thin film transistor T2. For example, the first planarization layer 115a may be made of an organic material such as acryl resin, epoxy resin, phenolic resin, polyamide resin, polyimide resin, etc.

The auxiliary electrode 145 is disposed on the first planarization layer 115a.

The auxiliary electrode 145 may be connected to the second drain electrode D2 of the second thin film transistor T2 through a contact hole of the first planarization layer 115a. The auxiliary electrode 145 may serve to electrically connect the second thin film transistor T2 and the first electrode 121. In addition, the auxiliary electrode 145 may be configured by a single layer or multiple layers made of any one of molybdenum (Mo), copper (Cu), titanium (Ti), aluminum (Al) chromium (Cr), gold (AU), nickel (Ni), and neodymium (Nd), or an alloy thereof. The auxiliary electrode 145 may be made of the same material as the second source electrode S2 and the second drain electrode D2 of the second thin film transistor T2.

A second planarization layer 115b of the planarization layer 115 is disposed on the auxiliary electrode 145 and the first planarization layer 115a.

For example, the second planarization layer 115b may be made of an organic material such as acryl resin, epoxy resin, phenolic resin, polyamide resin, polyimide resin, etc.

The light emitting diode 120 is disposed on the second planarization layer 115b. The light emitting diode 120 includes the anode electrode 121, the light emitting layer 122, and the cathode electrode 123.

Further, a bank 116a of the bank part 116 is disposed on the second planarization layer 115b. The bank 116a may include an open area for exposing a portion corresponding to a light emitting area of each subpixel.

The anode electrode 121 of the light emitting diode 120 is disposed on the second planarization layer 115b. The anode electrode 121 may be made of the metallic material, and may be electrically connected to the auxiliary electrode 145 through the contact hole provided on the second planarization layer 115b. For example, when the display apparatus 100 according to an exemplary embodiment of the present disclosure is a top emission type, the light emitted by the light emitting diode 120 may be emitted to the upper portion of the substrate 110, and at this time, the anode electrode 121 may further include a transparent conductive layer and a reflection layer on the transparent conductive layer. For example, the transparent conductive layer may be made of a transparent conductive oxide such as ITO, IZO, etc., and the reflection layer may be made of silver (Ag), aluminum (Al), gold (Au), molybdenum (Mo), tungsten (W), chromium (Cr) or an alloy thereof.

The bank 116a may be disposed while covering both ends of the anode electrode 121, and a part of the anode electrode 121 may be exposed through an open area of the bank 116a. For example, the bank 116a may be made of the inorganic insulation material such as silicon nitride (SiNx) or silicon oxide (SiOx), or the organic insulation material such as benzocyclobutene-based resin, acrylic resin, or imide-based resin, but is not limited thereto. A spacer 116b of the bank part 116 may be further disposed on the bank 116a.

The light emitting layer 122 of the light emitting diode 120 is disposed at an open area of the bank 116a and on a periphery thereof. As a result, the light emitting layer 122 may be disposed on the anode electrode 121 exposed through the open area of the bank 116a. For example, the light emitting layer 122 may include a plurality of organic films. The cathode electrode 123 is disposed on the light emitting layer 122 of the light emitting diode 120.

The encapsulation layer 117 is disposed on the light emitting diode 120.

The encapsulation layer 117 may have a single-layer structure or a multi-layer structure. For example, as illustrated in FIG. 5, the encapsulation layer 117 may include a first encapsulation layer 117a, a second encapsulation layer 117b, and a third encapsulation layer 117c. At this time, the first encapsulation layer 117a and the third encapsulation layer 117c may be configured by inorganic films, and the second encapsulation layer 117b may be configured by the organic film. Among the first encapsulation layer 117a, the second encapsulation layer 117b, and the third encapsulation layer 117c, the second encapsulation layer 117b may be the thickest and may serve as the planarization layer.

In the encapsulation layer 117, the first encapsulation layer 117a may be disposed most adjacent to the light emitting diode 120. That is, the first encapsulation layer 117a may be disposed on the cathode electrode 123 of the light emitting diode 120.

The first encapsulation layer 117a may be made of an inorganic insulation material which is enabled to be subject to low-temperature deposition. For example, the first encapsulation layer 117a may be made of silicon nitride (SiNx), silicon oxide (SiOx), silicon oxynitride (SiON), or aluminum oxide (Al2O3). Since the first encapsulation layer 117a is deposited at a low-temperature atmosphere, the light emitting layer 122 containing the organic material which is vulnerable to a high-temperature atmosphere may be suppressed from being damaged upon a deposition process.

The second encapsulation layer 117b may be formed with a smaller area than the first encapsulation layer 117a. In this case, the second encapsulation layer 117b may be formed to expose both ends of the first encapsulation layer 117a. The second encapsulation layer 117b may play a buffering role of buffering stress between respective layers by the bending of a flexible display apparatus, and play a role in strengthening planarization performance. For example, the second encapsulation layer 117b may be made of an organic insulation material such as acryl resin, epoxy resin, polyimide, polyethylene, or silicon oxycarbon (SiOC). For example, the second encapsulation layer 117b may also be formed through an inkjet scheme, but is not limited thereto.

The third encapsulation layer 117c may be formed on the top of the substrate 110 where the second encapsulation layer 117b is formed so as to cover a top surface and a side surface of each of the second encapsulation layer 117b and the first encapsulation layer 117a. At this time, the third encapsulation layer 117c may minimize or block, or at least reduce penetration of external moisture or oxygen into the first encapsulation layer 117a and the second encapsulation layer 117b. For example, the third encapsulation layer 117c may be made of the inorganic insulation material such as silicon nitride (SiNx), silicon oxide (SiOx), silicon oxynitride (SiON), or aluminum oxide (Al2O3).

At least one blocking structure DAM blocking a flow of the second encapsulation layer 117b of the encapsulation layer 117 may be disposed in the non-display area NA.

In the display apparatus 100 according to an exemplary embodiment of the present disclosure, a color filter, a touch sensor, and the like may be further disposed on the encapsulation part 117, but the present disclosure is not limited thereto.

For example, as illustrated in FIG. 5, a buffer film 118 which may be a touch buffer film for placing the touch sensor may be further disposed on the third encapsulation layer 117c.

The buffer film 118 may suppress the damage of the light emitting layer 122 of the light emitting diode 120 which is vulnerable to a chemical liquid or moisture, or high temperature. For example, when the touch sensor is formed, a chemical liquid (development liquid or etching liquid) used for a process or moisture from the outside may be generated. In order to suppress the chemical liquid or moisture during manufacturing the touch sensor from penetrating the light emitting layer 122 containing the organic material, the buffer film 118 may be disposed, and the touch sensor may be disposed thereon. Further, the buffer film 118 may be enabled to be formed at a low temperature of a predetermined temperature (e.g. 100° C.) or less, and may be made of an organic insulation material having a low dielectric constant of 1 to 3. For example, the buffer film 118 may be made of an acryl-based, or epoxy-based, or siloxane-based material.

Further, the buffer film 118 may suppress the damage of the encapsulation part 117 and breakage of the touch electrode of the touch sensor due to the bending of the flexible display apparatus. For example, the buffer film 118 is made of the organic insulation material and has the planarization performance, and as a result, even though the flexible display apparatus is bent, the damage of the encapsulation part 117 and a breakage phenomenon of the touch electrode may be suppressed.

For example, the touch electrode of the touch sensor may be disposed on the buffer film 118. The touch electrode may include touch sensor metal and bridge metal positioned on different layers, and a touch interlayer insulation film may be disposed between the touch sensor metal and the bridge metal. For example, the touch sensor metal may include first touch sensor metal, second touch sensor metal, and third touch sensor metal disposed adjacent to each other. The first touch sensor metal and the second touch sensor metal may be electrically connected to each other, and when the third touch sensor metal is positioned between the first touch sensor metal and the second touch sensor metal, the first touch sensor metal and the second touch sensor metal may be electrically connected through the bridge metal on a different layer. The bridge metal may be insulated from the touch sensor metal by the touch interlayer insulation film.

In the display apparatus 100 according to an exemplary embodiment of the present disclosure, an organic material layer covering the color filter and the touch sensor may be further disposed on the encapsulation part 117. For example, the organic material layer covering the touch electrode of the touch sensor may be disposed, and the organic material layer may be configured by an organic insulation film.

Further, in the display apparatus 100 according to an exemplary embodiment of the present disclosure, a polarization layer and a cover layer may also be further disposed on such an organic material layer on the encapsulation part 117.

The polarization layer may suppress reflection of external light on the display area DA. For example, when the display apparatus 100 is externally used, external natural light may be introduced and reflected by the reflection layer included in the anode electrode 121 of the light emitting diode 120, or reflected by an electrode made of metal disposed below the light emitting diode 120. An image of the display apparatus 100 may not be well viewed by the reflected light. The polarization layer may polarize the light introduced from the outside in a specific direction and suppress the reflected light from being emitted to the outside of the display apparatus 100 again.

Further, a cover glass may protect the components of the display apparatus 100 from external shock, and suppress damage such as scratch, etc. The cover glass may be bonded by an adhesive layer on the polarization layer. For example, the adhesive layer may be formed by using an optically transparent display adhesive such as pressure sensitive adhesive, optical clear adhesive (OCA), optical clear resin (OCR), etc., but is not limited thereto.

Referring back to FIG. 3, the non-display area NA of the substrate 110 as an area where the image is not displayed is an area where various lines, circuits, etc., for driving the subpixels in the display area DA are disposed.

In the peripheral area PPHA of the substrate 110, gate driving parts GIPa and GIPb of the gate driver, a low-potential voltage line VSSL, a high-potential voltage line VDDL, at least one blocking structure DAM, and dummy metal DM1 may be disposed.

In addition, in the peripheral area PPHA of the substrate 110, various lines for electrically connecting subpixels disposed in the display area DA to the gate driving parts GIPa and GIPb, the low-potential voltage line VSSL, and the high-potential voltage line VDDL, respectively may be disposed.

Further, in the peripheral area PPHA of the substrate 110, various lines for electrically connecting a plurality of pads disposed in the pad area PA to the subpixels, the gate driving parts GIPa and GIPb, the low-potential voltage line VSSL, and the high-potential voltage line VDDL, respectively may be further disposed.

As illustrated in FIG. 3, the gate driving parts GIPa and GIPb may be disposed in the peripheral area PPHA of the substrate 110, and may be disposed at both sides of the display area DA, but are not limited thereto. The gate driving parts GIPa and GIPb provide a gate signal to the thin film transistor of the pixel driving circuit, and include various gate driving circuits. In the display apparatus 100 according to an exemplary embodiment of the present disclosure, the gate driving parts GIPa and GIPb may be gate-in panels (GIPs) in which the gate driving circuits are directly formed on the substrate 110.

The low-potential voltage line VSSL may be disposed in the peripheral area PPHA of the substrate 110, and may surround the display area DA, and may have an open loop shape in which both ends are separated at one area (i.e., the link area LA) of the peripheral area PPHA.

Further, the high-potential voltage line VDDL may be disposed at one area (i.e., the link area LA) of the peripheral area PPHA of the substrate 110, and disposed in a space between both ends of the low-potential voltage line VSSL.

Each subpixel disposed in the display area DA is electrically connected to the high-potential voltage line VDDL disposed in the non-display area NA through a high-potential power supply line to receive high-potential power supply VDD, and electrically connected to the low-potential voltage line VSSL through a low-potential power supply line to receive low-potential power supply VSS.

The dummy metal DMI may be disposed at one area (i.e., the link area LA) of the peripheral area PPHA, and disposed between the high-potential voltage line VDDL and the bending area BA.

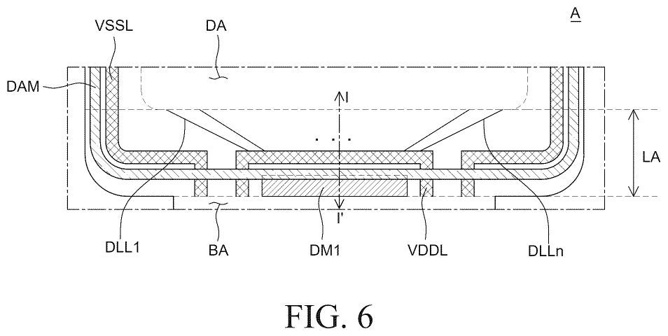

As such, the dummy metal DM1 is disposed at one area (i.e., the link area LA) of the peripheral area PPHA, and disposed at an area adjacent to the bending area BA of the substrate 110 to alleviate bending stress applied to the substrate 110 upon bending the substrate 110, thereby suppressing the damage to the display panel DP. The dummy metal DMI will be described in more detail in FIGS. 6 to 9 below.

As described above, both ends of the low-potential voltage line VSSL, the high-potential voltage line VDDL and the dummy metal DM1 may be disposed at the link area LA at one side facing the bending area BA of the peripheral area PPHA.

Further, the blocking structure DAM may be disposed in the peripheral area PPHA of the substrate 110, and the blocking structure DAM may block the flow of the organic film included in the encapsulation part disposed on the light emitting diode 120 of the subpixel.

As illustrated in FIG. 3, the blocking structure DAM may have a closed loop shape which entirely surrounds the display area DA. Further, the blocking structure DAM may be disposed not to overlap the low-potential voltage line VSSL throughout the peripheral area PPHA except for the link area LA on a plane, and may be disposed to overlap parts of the low-potential voltage line VSSL and the high-potential voltage line VDDL at the link area LA, but is not limited thereto.

In FIG. 3, it is illustrated that one blocking structure DAM is disposed in the peripheral area PPHA of the substrate 110 for easy description, but the number of blocking structures DAM and a height of the blocking structure DAM are not limited thereto. For example, a plurality of blocking structures DAM may be disposed to surround the display area DA, and heights of at least two of the plurality of blocking structures DAM may be the same as or different from each other.

Meanwhile, various link lines for transferring various signals or voltage to the lines disposed in the display area DA may be disposed at one side (i.e., the link area LA) of the peripheral area PPHA of the substrate 110. For example, a gate link line, a data link line, a high-potential voltage link line, a low-potential voltage link line, etc., may be disposed at the link area LA. As such, the respective link lines disposed at the link area LA may be extended and disposed to reach at least one of the bending area BA and the pad area PA.

For example, as illustrated in FIG. 3, a plurality of data link lines DLL1 to DLLn connected to the plurality of data lines DL1 to DLn disposed in the display area DA, respectively may be disposed at the link area LA. The plurality of data link lines DLL1 to DLLn may be extended up to the bending area BA and the pad area PA, and connected to a plurality of signal lines disposed in the pad area PA, respectively and electrically connected to a data pad connected to the signal line.

The pad area PA in the non-display area NA of the substrate 110 is an area where various lines and circuits for receiving external power, a data driving signal, etc., or transmitting/receiving a touch signal are disposed. A plurality of pads may be disposed in the pad area PA, and for example, a high-potential power supply pad, a data pad, a gate pad, a low-potential voltage supply pad, and the like may be disposed.

Further, an external module, e.g., a driving integrated circuit (IC) such as a data driver IC or a gate driver IC may be positioned in the pad area PA. The driving IC disposed in the pad area PA may be connected to a plurality of signal lines, and connected to a plurality of data lines DL or a plurality of gate lines GL disposed in the display area DA through the plurality of signal lines. That is, the driving IC disposed in the pad area PA may be electrically connected to each of the plurality of pixels P.

Hereinafter, referring to FIGS. 6 to 9, a structure of the voltage line and the dummy metal disposed in the non-display area NA of the substrate 110 in the display apparatus 100 according to an exemplary embodiment of the present disclosure will be described in detail.

However, a component among the components disposed in the non-display area NA of the substrate 110 illustrated in FIGS. 6 to 9, which use the same reference numeral as the components described through FIGS. 3 to 5 above may mean substantially the same component. Therefore, for easy description, a duplicated description of the same or similar component as the component described through FIGS. 3 to 5 above among the components disposed in the non-display area NA of the substrate 110 illustrated FIGS. 6 to 9, and the resulting feature is omitted.

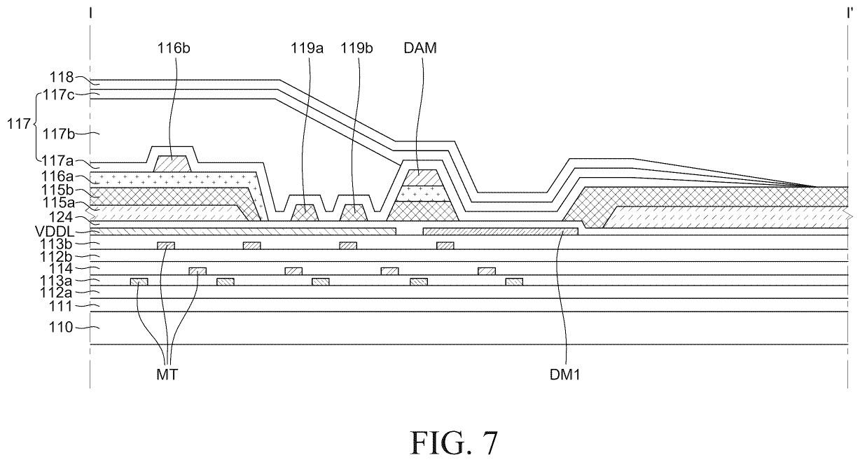

FIG. 6 is an enlarged view of part A of FIG. 3, which is to explain an example of the layout structure of the dummy metal of the display panel according to an exemplary embodiment of the present disclosure. In addition, FIG. 7 is a cross-sectional view taken along line I-I′ of FIG. 6.

Referring to FIG. 6, both ends of the low-potential voltage line VSSL, a part of the blocking structure DAM, the high-potential voltage line VDDL, and the dummy metal DM1 are disposed at one side (i.e., the link area LA) of the peripheral area PPHA adjacent to the bending area BA on the substrate 110.

The link area LA of the substrate 110 may include a first area in which one end of both ends of the low-potential voltage line VSSL is disposed, a second area in which the other end of both ends of the low-potential voltage line VSSL is disposed, and a third area positioned between the first and second areas, in which the high-potential voltage line VDDL is disposed. For example, based on a reference line passing through a center point of the display area DA and a center point of the bending area BA, both ends of the low-potential voltage line VSSL may be disposed in an outer part of the substrate 110 than the high-potential voltage line VDDL.

The high-potential voltage line VDDL may be a bar shape having a predetermined length, in which the high-potential voltage line VDDL is disposed in parallel to a boundary line of the display area DA and a boundary line of the bending area BA, but is not limited thereto. The high-potential voltage line VDDL may be a form in which the high-potential voltage line VDDL itself may be bent on both ends toward the bending area BA, and extended up to the bending area BA, but is not limited thereto. For example, the signal line extended from the bending area BA may also be connected to a bar-shaped portion of the high-potential voltage line VDDL.

A portion in the high-potential voltage line VDDL, which is disposed in parallel to the boundary line with the display area DA and the boundary line with the bending area BA is disposed at an inner side of the blocking structure DAM on the plane. Further, both ends of the high-potential voltage line VDDL may be disposed to be extended up to the outer side of the blocking structure DAM, and to reach the bending area BA. At this time, the inner side of the blocking structure DAM in the link area LA may mean an inner side toward the display area DA. On the contrary, the outer side of the blocking structure DAM in the link area LA may mean an outer side toward an opposite side (e.g., the bending area BA) to the display area DA.

In the link area LA, both ends of the low-potential voltage line VSSL may be a bar shape having a predetermined length, in which both ends are extended from a portion disposed in the peripheral area PPHA other than the link area LA, and disposed in parallel to the boundary line with the display area DA and the boundary line with the bending area BA, but are not limited thereto. For example, both ends of the low-potential voltage line VSSL may be a form in which the low-potential voltage line VSSL itself may be bent from the bar-shaped portion toward the bending area BA, and extended up to the bending area BA, but are not limited thereto. For example, the signal line extended from the bending area BA may be connected to a bar-shaped portion of both ends of the low-potential voltage line VSSL.

A portion on both ends of the low-potential voltage line VSSL, which is disposed in parallel to the boundary line with the display area DA and the boundary line with the bending area BA is disposed at the inner side of the blocking structure DAM on the plane. Further, both ends of the low-potential voltage line VSSL may be disposed to be extended up to the outer side of the blocking structure DAM, and to reach the bending area BA.

The blocking structure DAM may be disposed in a form of surrounding the display area DA in the peripheral area PPHA, and disposed not to overlap the portion disposed in parallel to the boundary line with the display area DA of each of the low-potential voltage line VSSL and the high-potential voltage line VDDL, and the boundary line with the bending area BA in the link area LA. That is, most of each of the low-potential voltage line VSSL and the high-potential voltage line VDDL in the link area LA may be disposed at the inner side of the blocking structure DAM. However, when both ends of each of the low-potential voltage line VSSL and the high-potential voltage line VDDL in the link area LA are bent toward the bending area BA, the blocking structure DAM may overlap a part of the portion where each of the low-potential voltage line VSSL and the high-potential voltage line VDDL is bent.

For example, the dummy metal DM1 is disposed between the high-potential voltage line VDDL and the bending area BA. For example, the dummy metal DM1 may be disposed between the bar-shaped portion having the predetermined length in the high-potential voltage line VDDL and the bending area BA, and disposed at the outer side of the blocking structure DAM. At this time, the dummy metal DM1 may be disposed so that a part thereof overlaps the blocking structure DAM, but is not limited thereto. Further, when the dummy metal DMI includes the portions where both ends of the high-potential voltage line VDDL are bent toward the banding area BA, the dummy metal DM1 may be disposed in a space between the portions of the high-potential voltage line VDDL extended toward the bending area BA.

Referring to FIG. 7, a first buffer layer 111, a first gate insulation layer 112a, a first interlayer insulation layer 113a, a second buffer layer 114, a second gate insulation layer 112b, a second interlayer insulation layer 113b, an inorganic material layer 124, a first planarization layer 115a, a second planarization layer 115b, a bank 116a, a spacer 116b, a first encapsulation layer 117a, a second encapsulation layer 117b, a third encapsulation layer 117c, and a buffer film 118 each extended from the display area DA may be sequentially disposed on the substrate 110 at one side (i.e., the link area LA) of the non-display area NA of the substrate 110.

A plurality of lines MT made of metal may be disposed on the first gate insulation layer 112a, the first interlayer insulation layer 113a, and the second gate insulation layer 112b. For example, various lines for electrically connecting subpixels disposed in the display area DA to the gate driving parts GIPa and GIPb, the low-potential voltage line VSSL, and the high-potential voltage line VDDL, respectively may be disposed on different layers. Further, various lines for electrically connecting a plurality of pads disposed in the pad area PA to the subpixels, the gate driving parts GIPa and GIPb, the low-potential voltage line VSSL, and the high-potential voltage line VDDL, respectively may be disposed on different layers. For example, at least some of the lines MT illustrated in FIG. 7 may be a plurality of data link lines DDL1 to DLLn connected to the plurality of data lines DL1 to DLn disposed in the display area DA, respectively, but are not limited thereto. At this time, the plurality of lines MT may be disposed on the same layer as at least one of the first gate electrode G1 of the first thin film transistor T1, the second capacitor electrode C2 of the storage capacitor Cst, and the second gate electrode G2 of the second thin film transistor T2, and may be made of the same material. The plurality of lines MT may be formed through the same process as at least one of the first gate electrode G1 of the first thin film transistor T1, the second capacitor electrode C2 of the storage capacitor Cst, and the second gate electrode G2 of the second thin film transistor T2.

The high-potential voltage line VDDL may be disposed on the second interlayer insulation layer 113b. For example, the high-potential voltage line VDDL may be disposed on the same layer as and made of the same material as at least one of the first source electrode S1 and the first drain electrode D1 of the first thin film transistor T1, and the second source electrode S2 and the second drain electrode D2 of the second thin film transistor T2 described in FIG. 5 above, but the present disclosure is not limited thereto. The high-potential voltage line VDDL may be formed through the same process as the first source electrode S1 and the first drain electrode D1 of the first thin film transistor T1, and the second source electrode S2 and the second drain electrode D2 of the second thin film transistor T2.

The dummy metal DM1 may be disposed on the second interlayer insulation layer 113b, and spaced apart and electrically insulated from the high-potential voltage line VDDL. For example, the dummy metal DM1 may be disposed on the same layer and made of the same material as the high-potential voltage line VDDL, but is not limited thereto. The dummy metal DM1 may be formed through the same process as the high-potential voltage line VDDL.

The inorganic material layer 124 is disposed to cover the high-potential voltage line VDDL and the dummy metal DM1.

The blocking structure DAM may be disposed on the inorganic material layer 124.

Further, the first planarization layer 115a and the second planarization layer 115b may be sequentially disposed on the inorganic material layer 124. For example, each of the first planarization layer 115a and the second planarization layer 115b may be separated from an area which overlaps the dummy metal DM1. That is, the blocking structure DAM may be disposed between the first planarization layer 115a and the second planarization layer 115b separated and spaced apart from each other. Further, the second planarization layer 115b may be disposed to cover the first planarization layer 115a.

The display apparatus 100 according to an exemplary embodiment of the present disclosure may include at least one blocking structure. For example, in FIG. 6, an example in which the display apparatus 100 includes one blocking structure DAM is illustrated, but in FIG. 7, another example in which the display apparatus 100 includes a plurality of blocking structures 119a, 119b, and DAM is illustrated. In FIG. 7, the plurality of blocking structures 119a, 119b, and DAM is disposed on the inorganic material layer 124.

A first blocking structure DAM among the plurality of blocking structures 119a, 119b, and DAM illustrated in FIG. 7 may be disposed farthest from the display area DA and disposed closest to the bending area BA. That is, the first blocking structure DAM may be a blocking structure disposed at an outermost side in the peripheral area PPHA. Further, each of a second blocking structure 119a and a third blocking structure 119b among the plurality of blocking structures 119a, 119b, and DAM may be disposed closer to the display area DA than the first blocking structure DAM. At this time, the second blocking structure 119a and the third blocking structure 119b may have a lower height than the first blocking structure DAM, but are not limited thereto.

The bank 116a and the spacer 116b of the bank part 116 may be disposed on the top of the first planarization layer 115a and the second planarization layer 115b. At this time, the bank part 116 may be disposed at an inner side than the blocking structures 119a, 119b, and DAM. Further, the bank 116a may be disposed to cover the second planarization layer 115b.

The encapsulation part 117 is disposed to cover the bank part 116 and the plurality of blocking structures 119a, 119b, and DAM.

At this time, the first encapsulation layer 117a and the third encapsulation layer 117c may be disposed on the first blocking structure DAM, and the flow of the second encapsulation layer 117b may be blocked by the first blocking structure DAM.

For example, as illustrated in FIG. 7, the first encapsulation layer 117a and the third encapsulation layer 117c may be disposed on the plurality of blocking structures 119a, 119b, and DAM, and extended over the first blocking structure DAM at the outermost side to cover the inorganic material layer 124. At this time, the first encapsulation layer 117a and the third encapsulation layer 117c may be extended along an outer portion of the first blocking structure DAM. Further, a flow velocity of the second encapsulation layer 117b may be lowered by the second blocking structure 119a and the third blocking structure 119b, and the flow is blocked by the first blocking structure DAM. That is, the flow of the second encapsulation layer 117b becomes slow by at least one of the plurality of blocking structures on an outer periphery of the non-display area NA, and a height from the substrate 110 is gradually decreased, and the flow may be blocked before the outermost blocking structure DAM or in contact with the outermost blocking structure DAM.

The first blocking structure DAM may be formed in a predetermined height or more in order to block the flow of the second encapsulation layer 117b. To this end, the first blocking structure DAM may be configured at least by one or more layers made of an organic material. For example, the first blocking structure DAM may include a lower layer made of the same material as any one of the first planarization layer 115a and the second planarization layer 115b, an intermediate layer made of the same material as the bank 116a, and an upper layer made of the same material as the spacer 116b, but is not limited thereto. Further, the second blocking structure 119a and the third blocking structure 119b may be made of the same material as any one of the first planarization layer 115a and the second planarization layer 115b.

Meanwhile, in the link area LA, the high-potential voltage line VDDL occupies a wide area in a width direction parallel to the boundary line with the display area DA and the boundary line with the bending area BA, and a current amount increases as a relatively higher voltage is applied than the low-potential voltage VSS, so film lifting may occur on the high-potential voltage line VDDL and upper layers thereof due to heat generated from lines. For example, referring to FIG. 7, the first encapsulation layer 117a and the third encapsulation layer 117c, and the buffer film 118 disposed on the top thereof are disposed to reach the bending area BA over the first blocking structure DAM, and heights are decreased in the vicinity of the bending area BA. When the high-potential voltage line VDDL is extended and disposed close up to the bending area BA to the outside of the first blocking structure DAM, the film lifting by the high-potential voltage line VDDL may easily occur on the first encapsulation layer 117a, the third encapsulation layer 117c, and the buffer film 118 which are in a relatively unstable state compared to other portions in the vicinity of the bending area BA. At this time, when moisture penetration occurs due to the film lifting in the vicinity of the bending area BA of the substrate 110, there is a problem in that moisture may penetrate up to the display area DA along the blocking structures 119a, 119b, and DAM. As a result, in the display apparatus 100 according to an exemplary embodiment of the present disclosure, the high-potential voltage line VDDL is disposed to be positioned at an inner side than at least one of the plurality of blocking structures 119a, 119b, and DAM to be far away from the bending area BA to suppress the film lifting by the high-potential voltage line VDDL, thereby suppressing a poor moisture penetration. In FIG. 7, an example in which the high-potential voltage line VDDL is disposed at an inner side than the first blocking structure DAM positioned at the outermost side in the link area LA is illustrated.

As described above, when the high-potential voltage line VDDL is disposed at the inner side than at least any one of the plurality of blocking structures 119a, 119b, and DAM in the link area LA, a plurality of layers made of the organic film and a plurality of lines are just disposed below the inorganic material layer 124 from the area where the plurality of blocking structures 119a, 119b, and DAM is disposed to the bending area BA. As a result, in the display apparatus 100 according to an exemplary embodiment of the present disclosure, the dummy metal DM1 is disposed to cover a similar area to the high-potential voltage line VDDL between the area where the plurality of blocking structures 119a, 119b, and DAM is disposed, and the bending area BA to alleviate bending stress applied to the substrate 110 upon bending the substrate 110. At this time, the dummy metal DMI is electrically insulated from the high-potential voltage line VDDL, and current does not flow, so heat is not generated, which does not cause the film lifting between the upper layers.

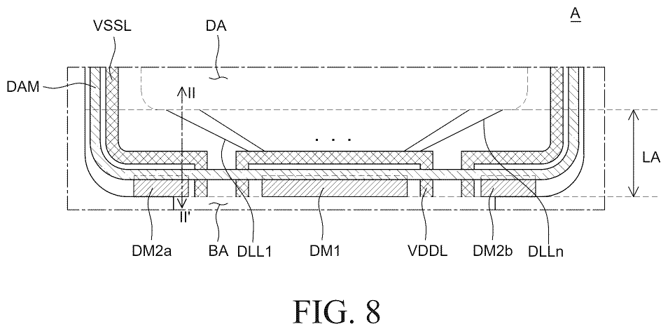

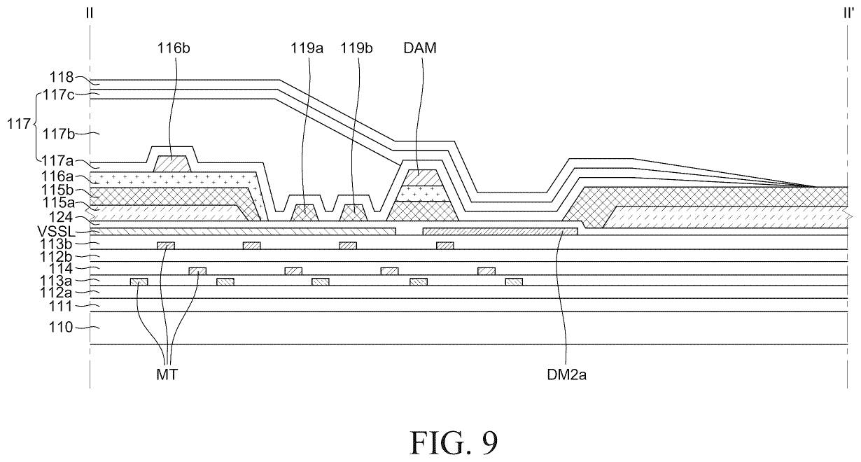

FIG. 8 is an enlarged view of part A of FIG. 3, which is to explain another example of the layout structure of the dummy metal of the display panel according to an exemplary embodiment of the present disclosure. In addition, FIG. 9 is a cross-sectional view taken along line II-II′ of FIG. 8.

Another example of the layout structure of the dummy metal of the display panel illustrated in FIGS. 8 and 9 includes substantially the same or similar components as one example described through FIGS. 6 and 7 above, and the resulting features except for the dummy metal DM2a and DM2b disposed on the periphery of the low-potential voltage line VSSL, so a description of the redundant components and the result features is omitted for easy description.

Referring to FIG. 8, in the link area LA of the substrate 110, the dummy metal DM2a is disposed in a first area where one end of both ends of the low-potential voltage line VSSL is disposed, and the dummy metal DM2b is disposed in a second area where the other end of both ends of the low-potential voltage line VSSL is disposed. The dummy metals DM2a and DM2b are disposed between both ends of the low-potential voltage line VSSL and the bending area BA. At this time, the dummy metals DM2a and DM2b are electrically insulated from the low-potential voltage line VSSL.

For example, the dummy metals DM2a and DM2b may be disposed between the bar-shaped portion having the predetermined length in the low-potential voltage line VSSL and the bending area BA, and disposed at the outer side of the blocking structure DAM. At this time, the dummy metals DM2a and DM2b may be disposed with parts thereof to overlap the blocking structure DAM, but are not limited thereto. Further, when the dummy metals DM2a and DM2b include the portions where both ends of the low-potential voltage line VSSL are bent toward the bending area BA, the dummy metals DM2a and DM2b may be disposed at the outer portion of the substrate 110 than the portions of the low-potential voltage line VSSL, which are extended toward the bending area BA. For example, based on a reference line passing through a center point of the display area DA and a center point of the bending area BA, the dummy metals DM2a and DM2b disposed adjacent to both ends of the low-potential voltage line VSSL may be disposed in an outer portion of the substrate 110 than the dummy metal DM1 disposed adjacent to the high-potential voltage line VDDL.

Referring to FIG. 9, the low-potential voltage line VSSL may be disposed on the second interlayer insulation layer 113b. For example, the low-potential voltage line VSSL may be disposed on the same layer as and made of the same material as at least one of the first source electrode S1 and the first drain electrode D1 of the first thin film transistor T1, and the second source electrode S2 and the second drain electrode D2 of the second thin film transistor T2 described in FIG. 5 above, but the present disclosure is not limited thereto. The low-potential voltage line VSSL may be formed through the same process as the first source electrode S1 and the first drain electrode D1 of the first thin film transistor T1, the second source electrode S2 and the second drain electrode D2 of the second thin film transistor T2, and the high-potential voltage line VDDL.

The dummy metals DM2a and DM2b may be disposed on the second interlayer insulation layer 113b, and spaced apart and electrically insulated from the low-potential voltage line VSSL. For example, as illustrated in FIG. 7, the dummy metal DM2a may be disposed on the same layer and made of the same material as the low-potential voltage line VSSL, but is not limited thereto. Further, the dummy metals DM2a and DM2b may be made of the same material and disposed on the same layer as the dummy metal DM1 disposed adjacent to the high-potential voltage line VDDL. The dummy metals DM2a and DM2b may be formed through the same process as at least one of the low-potential voltage line VSSL, the high-potential voltage line VDDL, and the dummy metal DM1.

As a result, in the display apparatus 100 according to an exemplary embodiment of the present disclosure, the dummy metal DM1 is disposed to cover a similar area to the high-potential voltage line VDDL between the area where the plurality of blocking structures 119a, 119b, and DAM is disposed, and the bending area BA, and at the same time, the dummy metals DM2a and DM2b may be additionally disposed to cover a similar area to the low-potential voltage line VSSL. Through this, the bending stress applied to the substrate 110 may be more effectively alleviated upon bending the substrate 110.

The exemplary embodiments of the present disclosure can also be described as follows:

According to an aspect of the present disclosure, there is provided a display apparatus. The display apparatus includes a substrate including a display area in which a plurality of pixels is disposed, and a non-display area outside the display area. The non-display area includes a first non-display area surrounding the display area and a second non-display area extended and bent at one side of the first non-display area. The display apparatus further includes a high-potential voltage line disposed at the one side of the first non-display area on the substrate, and supplying high-potential voltage to the plurality of pixels. The display apparatus further includes a first dummy metal disposed at the one side of the first non-display area on the substrate, disposed between the high-potential voltage line and the second non-display area, and electrically insulated from the high-potential voltage line.

The high-potential voltage line and the first dummy metal may be made of the same material, and disposed on the same layer.

The display apparatus may further include a blocking structure disposed at the one side of the first non-display area on the substrate, and disposed closer to the high-potential voltage line than to the second non-display area.

A part of the first dummy metal may overlap with the blocking structure, and the other part may be disposed between the blocking structure and the second non-display area.

The display apparatus may further include an inorganic material layer disposed to be extended from the display area to at least a part of the one side of the first non-display area on the substrate, and covering the high-potential voltage line and the first dummy metal. The blocking structure may be disposed on the inorganic material layer.

The display apparatus may further include a planarization layer extended from the display area to at least a part of the second non-display area on the substrate. The planarization layer includes a first part and a second part spaced apart from each other, and the first part and the second part of the planarization layer are separated from each other in an area which overlaps the first dummy metal.

The blocking structure is disposed in a space where the first part and the second part of the planarization layer are spaced apart from each other.

The blocking structure may contain the same material as the planarization layer.

The display apparatus may further include a low-potential voltage line disposed in the first non-display area on the substrate, and supplying low-potential voltage to the plurality of pixels. The low-potential voltage line surrounds the display area, and is disposed in an open loop shape in which both ends thereof are separated at the one side of the first non-display area.

The one side of the first non-display area may include a first area in which the one end of the low-potential voltage line is disposed, a second area in which the other end of the low-potential voltage line is disposed, and a third area in which the high-potential voltage line is disposed. The third area is disposed between the first area and the second area.

The display apparatus may further include a second dummy metal disposed in at least one of the first area and the second area at the one side of the first non-display area, disposed between the low-potential voltage line and the second non-display area, and electrically insulated from the low-potential voltage line.

The low-potential voltage line and the second dummy metal are made of the same material, and disposed on the same layer.

The second dummy metal may be disposed at an outer portion of the substrate than the first dummy metal based on a reference line passing through a center point of the display area and a center point of the second non-display area.

The first dummy metal and the second dummy metal may be made of the same material, and disposed on the same layer.

The display apparatus may further include a thin film transistor disposed in the display area on the substrate, and including an active layer, a gate electrode, a source electrode, and a drain electrode; and a light emitting diode disposed on the thin film transistor, and including a first electrode electrically connected to any one of the source electrode and the drain electrode, a light emitting layer disposed on the first electrode, and a second electrode disposed on the light emitting layer. The first dummy metal is made of the same material and disposed on the same layer as at least one of the source electrode and the drain electrode.

According to another aspect of the present disclosure, a display apparatus includes a substrate, including a display are a in which an image is displayed, a bending area that bends, and a link area extending in a first direction between the display area and the bending area. The display apparatus further includes a light-emitting element disposed on the substrate in the display area, and a thin film transistor disposed between the light-emitting element and the substrate in the display area. The thin film transistor is electrically connected to the light-emitting element. The display apparatus further includes a supply voltage line disposed in the link area. At least a part of the supply voltage line extends in the first direction traversing from the link area to the bending area. The display apparatus further includes a dummy metal adjacent to the supply voltage line in a second direction intersecting the first direction. The dummy metal is electrically insulated from the supply voltage line.

In some embodiments, the dummy metal and the supply voltage line are disposed in a same layer, and include a same material.

In some embodiments, the supply voltage line includes a high potential voltage line configured to supply a high potential voltage to the thin film transistor and the light-emitting element. The high potential voltage line is in an open loop shape with two ends in the link area. The dummy metal is disposed between the two ends of the high potential voltage line in the second direction.

In some embodiments, the supply voltage line includes a low potential voltage line configured to supply a low potential voltage to the thin film transistor and the light-emitting element. The low potential voltage line is in an open loop shape surrounding the display area with two ends in the link area. The dummy metal includes two dummy metals, each adjacent to a corresponding one of the two ends of the low potential voltage line.

In some embodiments, the two ends of the low potential voltage line are disposed between the two dummy metals in the second direction.

In some embodiments, the supply voltage line includes a high potential voltage line configured to supply a high potential voltage to the thin film transistor and the light-emitting element, a low potential voltage line configured to supply a low potential voltage to the thin film transistor and the light-emitting element. The low potential voltage line is in a first open loop shape surrounding the display area with two ends in the link area. The high potential voltage line is in a second open loop shape with two ends between the two ends of the low potential voltage line in the second direction. The dummy metal includes a first dummy metal disposed adjacent to a first end of the two ends of the low potential voltage line in the second direction, and a second dummy metal disposed adjacent to a second end of the two ends of the low potential voltage line in the second direction, and a third dummy metal disposed between the two ends of the high potential voltage line.

In some embodiments, the display apparatus further includes an encapsulation layer on the light-emitting element configured to enclose the light-emitting element and a blocking structure in the link area disposed between at least a part of the encapsulation layer and the dummy metal.

In some embodiments, the encapsulation layer includes a first encapsulation layer including an inorganic material, and a second encapsulation layer including an organic material. The first encapsulation layer extends over the blocking structure onto the dummy metal, while the blocking structure is disposed between the second encapsulation layer and the dummy metal.

In some embodiments, the blocking structure partially overlaps the dummy metal in plan view.

In some embodiments, the blocking structure includes a first blocking structure having a first height, and a second blocking structure having a second height greater than the first height. The first blocking structure at least partially overlaps the supply voltage line in plan view, and the second blocking structure at least partially overlaps the dummy metal in plan view.

In some embodiments, the display apparatus further includes a planarization layer extending across the display area and at least a part of the link area. The planarization layer includes a first part and a second part spaced apart from each other, and the dummy metal is disposed between the first part and the second part of the planarization layer.

In some embodiments, the blocking structure includes a same material as the planarization layer.

In some embodiments, the thin film transistor includes an active layer, a gate electrode, a source electrode, and a drain electrode. The dummy metal includes a same material and is disposed on a same layer as at least one of the source electrode or the drain electrode.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display apparatus comprising:
a substrate including a display area in which a plurality of pixels is disposed, and a non-display area outside the display area, wherein the non-display area includes a first non-display area surrounding the display area and a second non-display area extended and bent at one side of the first non-display area;
a high-potential voltage line disposed at the one side of the first non-display area on the substrate, and supplying high-potential voltage to the plurality of pixels; and
a first dummy metal disposed at the one side of the first non-display area on the substrate, disposed between the high-potential voltage line and the second non-display area, and electrically insulated from the high-potential voltage line.

2. The display apparatus of claim 1, wherein the high-potential voltage line and the first dummy metal are made of a same material, and disposed on a same layer.

3. The display apparatus of claim 1, further comprising:
a blocking structure disposed at the one side of the first non-display area on the substrate, and disposed closer to the high-potential voltage line than to the second non-display area.

4. The display apparatus of claim 3, wherein a part of the first dummy metal overlaps the blocking structure in plan view, and another part of the first dummy metal is disposed between the blocking structure and the second non-display area.

5. The display apparatus of claim 3, further comprising:
an inorganic material layer extending from the display area to at least a part of the one side of the first non-display area on the substrate, covering the high-potential voltage line and the first dummy metal.

6. The display apparatus of claim 5, wherein the blocking structure is disposed on the inorganic material layer.

7. The display apparatus of claim 5, further comprising:
a planarization layer extending from the display area to at least a part of the second non-display area on the substrate,
wherein the planarization layer includes a first part and a second part spaced apart from each other, and the first dummy metal is disposed between the first part and the second part of the planarization layer.

8. The display apparatus of claim 7, wherein the blocking structure is disposed in a space where the first part and the second part of the planarization layer are spaced apart from each other.

9. The display apparatus of claim 7, wherein the blocking structure includes a same material as the planarization layer.

10. The display apparatus of claim 1, further comprising:
a low-potential voltage line disposed in the first non-display area on the substrate, and supplying a low-potential voltage to the plurality of pixels,
wherein the low-potential voltage line surrounds the display area, and is disposed in an open loop shape with both ends separated at the one side of the first non-display area.

11. The display apparatus of claim 10, wherein the one side of the first non-display area includes:
a first area in which a first end of the low-potential voltage line is disposed,
a second area in which a second end of the low-potential voltage line is disposed, and
a third area in which the high-potential voltage line is disposed, the third area disposed between the first area and the second area.

12. The display apparatus of claim 11, further comprising:
a second dummy metal disposed in at least one of the first area or the second area at the one side of the first non-display area between the low-potential voltage line and the second non-display area, wherein the second dummy metal is electrically insulated from the low-potential voltage line.

13. The display apparatus of claim 12, wherein the low-potential voltage line and the second dummy metal are made of a same material, and disposed on a same layer.

14. The display apparatus of claim 12, wherein the first dummy metal and the second dummy metal are made of a same material, and disposed on a same layer.

15. The display apparatus of claim 1, further comprising:
a thin film transistor disposed in the display area on the substrate, and including an active layer, a gate electrode, a source electrode, and a drain electrode; and
a light emitting diode disposed on the thin film transistor, the light emitting diode including:
a first electrode electrically connected to any one of the source electrode or the drain electrode,
a light emitting layer disposed on the first electrode, and
a second electrode disposed on the light emitting layer,
wherein the first dummy metal includes a same material and is disposed on a same layer as at least one of the source electrode or the drain electrode.

16. A display apparatus, comprising:
a substrate, including a display area in which an image is displayed, a bending area that bends, and a link area extending in a first direction between the display area and the bending area;
a light-emitting element disposed on the substrate in the display area;
a thin film transistor disposed between the light-emitting element and the substrate in the display area, the thin film transistor electrically connected to the light-emitting element;
a supply voltage line disposed in the link area, at least a part of the supply voltage line extending in the first direction traversing from the link area to the bending area; and
a dummy metal adjacent to the supply voltage line in a second direction intersecting the first direction, wherein the dummy metal is electrically insulated from the supply voltage line.

17. The display apparatus of claim 16, wherein the dummy metal and the supply voltage line are disposed in a same layer, and include a same material.

18. The display apparatus of claim 16, wherein the supply voltage line includes a high potential voltage line configured to supply a high potential voltage to the thin film transistor and the light-emitting element, the high potential voltage line is in an open loop shape with two ends in the link area, and the dummy metal is disposed between the two ends of the high potential voltage line in the second direction.

19. The display apparatus of claim 18, wherein the supply voltage line includes a low potential voltage line configured to supply a low potential voltage to the thin film transistor and the light-emitting element, the low potential voltage line is in an open loop shape surrounding the display area with two ends in the link area, and wherein the dummy metal includes two dummy metals, each adjacent to a corresponding one of the two ends of the low potential voltage line.

20. The display apparatus of claim 19, wherein the two ends of the low potential voltage line are disposed between the two dummy metals in the second direction.

21. The display apparatus of claim 16, wherein the supply voltage line includes:
a high potential voltage line configured to supply a high potential voltage to the thin film transistor and the light-emitting element, and a low potential voltage line configured to supply a low potential voltage to the thin film transistor and the light-emitting element, wherein the low potential voltage line is in a first open loop shape surrounding the display area with two ends in the link area, wherein the high potential voltage line is in a second open loop shape with two ends between the two ends of the low potential voltage line in the second direction, wherein the dummy metal includes:
a first dummy metal disposed adjacent to a first end of the two ends of the low potential voltage line in the second direction;
a second dummy metal disposed adjacent to a second end of the two ends of the low potential voltage line in the second direction; and
a third dummy metal disposed between the two ends of the high potential voltage line.

22. The display apparatus of claim 16, the display apparatus further comprising:
an encapsulation layer on the light-emitting element configured to enclose the light-emitting element; and
a blocking structure in the link area disposed between at least a part of the encapsulation layer and the dummy metal.

23. The display apparatus of claim 22, wherein the encapsulation layer comprises a first encapsulation layer including an inorganic material, and a second encapsulation layer including an organic material, wherein the first encapsulation layer extends over the blocking structure onto the dummy metal, while the blocking structure is disposed between the second encapsulation layer and the dummy metal.

24. The display apparatus of claim 22, wherein the blocking structure partially overlaps the dummy metal in plan view.

25. The display apparatus of claim 22, wherein the blocking structure includes a first blocking structure having a first height, and a second blocking structure having a second height greater than the first height, the first blocking structure at least partially overlaps the supply voltage line in plan view, and the second blocking structure at least partially overlaps the dummy metal in plan view.

26. The display apparatus of claim 22, further comprising a planarization layer extending across the display area and at least a part of the link area, wherein the planarization layer includes a first part and a second part spaced apart from each other, and the dummy metal is disposed between the first part and the second part of the planarization layer.

27. The display apparatus of claim 26, wherein the blocking structure includes a same material as the planarization layer.

28. The display apparatus of claim 16, wherein the thin film transistor includes an active layer, a gate electrode, a source electrode, and a drain electrode, and wherein the dummy metal includes a same material and is disposed on a same layer as at least one of the source electrode or the drain electrode.
